(19) United States
(12) Patent Application Publication
(10) Pub. No.: US 2005/0072461 A1
(43) Pub. Date: Apr. 7, 2005

(54) Pinhole porosity free insulating films on flexible metallic substrates for thin film applications

(76) Inventors: Frank Kuchinski, Chelmsford, MA (US); Ronald Martin, Chelmsford, MA (US); Somesh Mukherjee, Lowell, MA (US)

Correspondence Address: Pepper Hamilton LLP;50th Floor, One Mellon Center, 500 Grant Street, Pittsburgh, PA, 15219, US

(21) Appl. No.: 10/856,746

(22) Filed: May 27, 2004

Related U.S. Application Data
(60) Provisional application No. 60/473,514, filed on May 27, 2003.

(51) Int. Cl. H01L 31/00

(52) U.S. Cl. 136/256; 136/244

(57) ABSTRACT

Monolithically integrated solar cells produced at high temperatures on high temperature metal substrates are disclosed. The coatings are thin-film and the insulating layer is pinhole and porosity-free. The methods and devices disclosed enable cost-effective, high performing monolithically integrated photovoltaic modules using Copper Indium Gallium di-Selenide (CIGS) films to be made on the dielectric coated metallic substrates. Embodiments of the invention include deposition methods as well as selection of particular insulating materials for deposition on a thermally stable substrate based on the coating's band gap energy, dielectric constant, and coefficient of thermal expansion (CTE). Tandem CIGS solar cells monolithically integrated on flexible substrates may also be produced by the methods and materials disclosed. The tandem solar cell devices include an upper solar cell, a lower solar cell, and an intermediate buffer layer with a tunnel junction. The high bandgap energy is absorbed by the upper solar cell, while lower bandgap energy passes through the upper solar cell and is absorbed by the lower solar cell.

### CROSS REFERENCES

This application claims the benefit of U.S. Provisional Application No. 60/473,514 filed May 27, 2003 the contents of which are incorporated herein by reference in their entirety.

### GOVERNMENT INTERESTS

This invention was made with Government support under Contract Number F29601-02-C-0168 awarded by USAF Department of Defense and with Government support under Contract Number F29601-03-C-0027 awarded by USAF Department of Defense. The Government has certain rights in the invention.

### BACKGROUND

The high efficiency and excellent stability of Copper Indium Gallium di-Selenide (CIGS) thin film solar cells provides a useful solar electricity generating system. CIGS deposition technology requires very high processing temperature, 450-600° C. for higher efficiency, and therefore device fabrication oftern takes place on metallic foil substrates. These are the only flexible substrates that can withstand this high temperature processing. The inherent electrical conductivity of these metallic substrates precludes monolithic device integration, which requires series connection of solar cells for panels.

Photovoltaic modules have traditionally been produced on an individual basis and then through a series of distinct steps the individual cells are combined and connected in series to give accumulated power in a “module”. This module, which typically consists of individual cells arranged in a square or rectangular pattern, may subsequently be assembled into an array of modules at the end use site.

In monolithic device integration, for example, solar cells are connected in series to form modules, where the cells and functional portion of the modules are produced concurrently. The modules are subsequently completed and the electrical connections are made. The modules are then typically arranged into arrays, usually at or near the point of use. The conductivity of the metallic substrate requires a dielectric or insulating layer to isolate the individual cells electrically enabling electrical connectivity by connection in series. Thus, the key to implementing monolithic processes on such substrates is the incorporation of an insulating layer between the CIGS and the metallic substrate. A film which is pinhole porosity free insulating layer prevents electrical shorting and thus enables monolithic integration for CIGS.

Recently, certain processes have been developed for monolithically integrating modules made from thin film processes, such as amorphous silicon. There have also been processes developed using CIGS (Copper Indium Gallium di-Selenide) and Cd—Te solar cells and their modules. It is widely known that the properties of CIGS, defined at the stable cell efficiency, are much improved when processed at high temperatures, usually above 550 degrees C. and which require high temperature substrates, like metal, because plastics, such as polyamide, can only be effectively processed at temperatures below 450 degrees C. Therefore metallic substrates, such as Stainless Steel, Molybdenum, aluminum, or Titanium foils, are candidates as substrates material for CIGS thin film solar cell which needed to be deposited at or above 550 degree C. for higher efficiency. However, these conducting metallic substrates require a dielectric layer for electrical isolation between the cells to allow them to be connected in series, from positive to negative, and therefore the modules can produce accumulated power from the individual cells composing the modules.

It would be desirable to make a non-porous and void free insulating film that adheres to a flexible and thermally stable substrate. This substrate could undergo further processing at high temperatures required for thin film applications such a solar cell manufacturing. CIGS based tandem solar cells could results in greater efficiency than single cells, and monolithic fabrication of such cells would allow low cost production methods to be used.

### SUMMARY

Embodiments of the present invention are directed to high-temperature withstanding, pinhole porosity-free insulating thin film coatings on metallic substrates and method for making them. This invention will enable the development of a cost-effective, high performing monolithically integrated photovoltaic module using light absorbing semiconductor materials such as Copper Indium Gallium di-Selenide (CIGS) films on insulated metallic substrates. One embodiment of the invention is selection of particular insulating materials for deposition on a thermally stable substrate based on band gap energy, dielectric constant, coefficient of thermal expansion (CTE), thermal stability, and chemical stability.

Embodiments of the present invention include thin film tandem, multijunction, or hybrid, solar cell modules monolithically formed on a flexible substrate and a process for making such tandem solar cells. The tandem solar cell device includes an upper solar cell, a lower solar cell, and an intermediate buffer layer. The high band gap energy light, short wavelength region of the incident light is absorbed by the upper solar cell while the light having passed through the upper solar cell is absorbed by the lower solar cell. The buffer layer is a semiconductor layer having a larger band gap energy than the upper solar cell, a crystalline lattice match with the upper solar cell, and a tunnel junction.

Embodiments of the invention deposit suitable insulating layers on metallic substrates, such as alloys like stainless steel, and metals like molybdenum, aluminum or titanium. Some of the challenges that the present invention overcomes are poor thermal and dimensional stability, poor thermal conductivity, poor adherence of the film, too large a difference in CTE values of the cell constituents for long term stability, mechanical strength, band gap matching, dielectric properties and thermally induced substrate warping. Prior to this development, the options available were very limited as most of the good dielectric materials are made of porcelain, glass, or plastic. These materials generally cannot be used in such applications as PV cells because of other poor properties and technical incompatibilities or temperature limitations with the CIGS system.

The present invention makes a thin film insulating layer on a thermally stable substrate; the insulating layer is pinhole porosity free. The insulating film and substrate allows for further high temperature, above 550° C., processing that may be used to improved CIGS cell efficiency characteristics and enable production of monolithically integrated photovoltaic modules. The process includes depositing a series of coatings in selective geometries on an insulator coated metal substrate such that not only are photovoltaic cells manufactured, but also the modules are co-manufactured and subsequently the cells are interconnected yielding modules which are functional upon encapsulation and electrical connection.

One embodiment of the present invention is a modified state-of-the-art deposition process, Ion assisted Physical Vapor deposition, with optimized process parameters and thickness which produces a pinhole porosity-free and compatible insulating film on a metal substrate. These insulating films may be aluminum nitride, magnesium oxide, or other semi-conducting materials, and will enable the development of thin film CIGS and their monolithic integration. The methods and substrates of the present invention can also be effectively used in other device fabrication applications, such as switches and transistors, which require high temperature processing.

One embodiment of the present invention includes a thermally stable substrate coated with a wide band gap semiconductor film. The wide band gap semiconductor film being adherent to the thermally stable substrate. The coating of the wide band gap semiconductor on the thermally stable substrate may be made by a physical vapor deposition or by an ion assisted physical vapor deposition process.

One embodiment of the present invention includes a thermally stable substrate with an adherent film of a wide band gap semiconductor deposited on at least one area of the thermally stable substrate. A conductive film, which is electrically insulated from the thermally stable substrate, is deposited on the wide band gap semiconductor film area. These conductive film areas may then be coated with a light absorbing semiconductor composition over at least a portion of the conductive film area.

One embodiment of the present invention is a method of making a substrate for photovoltaic cells. The method includes the acts of depositing a wide band gap semiconductor film on at least one area of a thermally stable substrate by a physical vapor deposition process. Preferably the wide band gap semiconductor is chosen to have a coefficient of thermal expansion similar to the thermally stable substrate. The method may also include the act of depositing a conductive film on a at least a portion of the wide band gap semiconductor film.

One embodiment of the present invention is a substrate on which a plurality of photovoltaic cells may be made. The substrate includes a thermally stable substrate and a layer of a wide bandgap semiconductor material. The wide bandgap semiconductor layer may coat one or more areas of the thermally stable substrate and it adheres to the thermally stable substrate. The substrate also includes a conductive layer on the wide bandgap semiconductor layer. The conductive layers can be used for electrically connecting subsequently formed photovoltaic cells in series.

One embodiment of the present invention is a method of making photovoltaic cells that includes annealing a light absorbing semiconductor composition which coats a portion of a conductive film at a temperature sufficient to increase the grain size of the light absorbing semiconductor composition. The conductive film on which the light absorbing semiconductor composition is deposited covers a portion of an adherent wide bandgap semiconductor film covering at least a portion of a thermally stable substrate.

Another embodiment of the present invention is a method of making monolithically integrated photovoltaic cell substrates which includes coating a thermally stable substrate with a wide bandgap semiconductor to form a first layer on the thermally stable substrate. Areas of the wide bandgap semiconductor layer are selectively coated with a composition to form one or more electrically conductive areas on the first layer. The electrically conductive areas are further coated with a light absorbing semiconductor composition.

Other embodiments of the present invention are monolithic photovoltaic cells connected in series and a methods for making such devices. Other embodiments of the present invention are monolithic photovoltaic cells including monolithic integration of multijunction tandem or “hybrid” solar cells onto substrates which may also be connected in series.

Multijunction photovoltaic cells on a thermally stable substrate, preferably a thermally stable substrate, in an embodiment of the present invention builds a single CIGS solar cell upon which is built a second solar cell. The top solar cell will absorb solar energy from about 1.7 e-volts and above while the bottom cell will absorb 1.1 electron volts or above. Preferably the top and bottom solar cells are separated by a buffer layer having a tunnel junction and whose lattice properties match those of the adjacent top and bottom cell layers.

A pinhole porosity free insulating layer is preferred to obtain the highest efficiency from CIGS for monolithic photovoltaic (PV) integration. Monolithic integration of solar cell on substrates is essential for large-scale solar cell production and for its commercial viability. Monolithic integration utilizing the present invention can be done by roll to roll processing to achieve the Photovoltaic Industry's Roadmap goals of improving cell efficiency and manufacturing throughput, and leading to lower cost PV energy and ultimately being economically competitive with the cost of conventional energy.

Photovoltaics (PV) is a versatile means to produce electricity for a wide variety of applications. This technology can be used for residential or remote power generation, power for portable devices, and space craft power generation. The present invention will help to increase the efficiency of PV cells and thus reduce the price of electricity using photovotaics. Other potential areas of application include, generating electricity, PV with battery storage, PV with generators, PV connected to utilities, Utility-scale power, and Hybrid power systems. The flexible and thin film nature of these products lend themselves to manufacturing techniques not possible with the crystalline materials like GaAs.

In embodiments of the present invention mask used can be limited strategically during CIGS cell fabrication to provide interconnection between the electrode without using laser/mechanical scribing and monolithic fabrication of such cells would allow low cost, ease of fabrication and high efficiency. In addition the flexible metallic substrates coated with an adherent material can serve as a base for thin film flexible tandem solar cells using CIGS as bottom cell and could provide efficiency and be more cost effective to make than any existing tandem cells.

### DESCRIPTION OF THE DRAWINGS

In part, other aspects, features, benefits and advantages of the embodiments of the present invention will be apparent with regard to the following description, appended claims and accompanying drawings where:

FIG. 1 is an as deposited AlN film on a stainless steel foil;

FIG. 2 is an SEM of an AlN film on stainless steel foil after thermal cycling;

FIG. 3 is an SEM picture showing an AlN film on a molybdenum substrate;

FIG. 4 is an SEM of an AlN film on molybdenum foil after thermal cycling;

FIG. 5 is an SEM micrograph of an MgO film on a molybdenum foil, as deposited, showing a smooth microsuructure;

FIG. 6 is an SEM micrograph of MgO on stainless steel foil, as deposited, showing a smooth microsuructure;

FIG. 7A is an SEM of a thermally cycled film of MgO on stainless steel foil showing a stable microsturcture; FIG. 7B is an EDAX of the film illustrating that no new phases were formed by the thermal treatment;

FIG. 8A is an SEM picture of a thermally cycled film of an MgO film on molybdenum foil illustrating a smooth microstructure; FIG. 8B is an EDAX of the film illustrating that no new phases were formed by the thermal treatment;

FIG. 9A is a illustration of an example of a typical thin film structure making up the photovoltaic device (the current collecting Ni/Al grid structure is omitted from the illustration); FIG. 9B is an illustration of a photovoltaic cell on a molybdenum substrate with the current collecting Ni/Al grid shown;

FIG. 10 schematically illustrates representative process steps for making photovoltaic solar cells of the present invention;

FIG. 11 schematically illustrates monolithically integrated solar cell panels on a flexible substrate, with cells electrically connected in series; the thermally stable flexible substrate (30) includes for example multiple cells (40) and (80) that are connected in series from the lower electrode portion of the cell (50) to the upper electrode metal grid portion of the cell (70) by a conductor (60); each of the six cells may be interconnect in the manner and the voltage output from the monolithic cell available from connectors labeled (+) and (−);

FIG. 12 illustrates a reactor for coating and annealing flexible thermally stable substrates, the substrates having a layer of wide bandgap semiconductor and one or more electrodes, with a light absorbing semiconductor layer that optionally includes a dopant like sodium;

FIG. 13 is a Table of photovoltaic cell CIGS layer composition for various cells made by the methods and materials in embodiments of the present invention;

FIG. 14A is a non-limiting illustration of photovoltaic cells (A) and (B) on a flexible thermally stable substrate (100) each with areas of wide bandgap semiconductor (110) on portions of the substrate (100), each cell includes an electrode (120), a semiconductor layer (130), buffer layer (140) and conductive semi-transparent oxide layers (150) and (160) and metal grid (170), the cells (A) and (B) may be interconnected by conductor (180); FIG. 14B is a non-limiting illustration of photovoltaic cells (C) and (D) on a flexible thermally stable substrate (200) a layer of a wide bandgap semiconductor (210) on portions of the substrate (200), each cell (C) and (D) includes an electrode (220), a semiconductor layer (230), buffer layer (240) and conductive semi-transparent oxide layers (250) and (260) and metal grid (270), the cells (C) and (D) may be interconnected by conductor (280);

FIG. 15A is an illustration of a flexible thermally stable substrate (300) coated with an insulating film layer (310) over a portion of the substrate (300); FIG. 15B is an illustration of one or more electrode pads (320) deposited on the insulating layer (310); FIG. 15C illustrates several tandem or multijunction solar cell devices on a flexible metallic base substrate (302) with a wide bandgap semiconductor isolation layer (312) and molybdenum or other conductive electrodes (322), each tandem solar cell includes an upper solar cell (330) having a higher band gap layer ≧1.7 eV, a lower solar cell (340) having a low band gap absorption layer ≧1.1 to 1.7 eV, and tunnel junction (350) portion; the absorption by various cells in the tandem cell are also illustrated; multijunction tandem cells may be connected in series (not shown);

FIG. 16 is a Table of representative CIGS solar cells and their characteristics, the substrates for the cells were coated with the insulator by an experimental batch process using ion beam assisted deposition, various substrate and insulator combinations including soda lime glass substrates (SLG) are listed in the Table;

FIG. 17 is a Table of representative CIGS solar cells and their characteristics, the insulating or wide bandgap semiconductor dielectric layer was deposited onto flexible substrates prepared on an experimental roll to roll web coating process with ion beam assisted deposition coating, various substrate and insulator combinations including soda lime glass substrates (SLG) are listed in the Table.

FIG. 18 is an illustration of a multijunction solar cell deposited on a dielectric material that coats a flexible and thermally stable metallic substrate.

### DETAILED DESCRIPTION

Before the present compositions and methods are described, it is to be understood that this invention is not limited to the particular molecules, compositions, methodologies or protocols described, as these may vary. It is also to be understood that the terminology used in the description is for the purpose of describing the particular versions or embodiments only, and is not intended to limit the scope of the present invention which will be limited only by the appended claims.

It must also be noted that as used herein and in the appended claims, the singular forms “a”, “an”, and “the” include plural reference unless the context clearly dictates otherwise. Thus, for example, reference to a “cell” is a reference to one or more cells and equivalents thereof known to those skilled in the art, and so forth. Unless defined otherwise, all technical and scientific terms used herein have the same meanings as commonly understood by one of ordinary skill in the art. Although any methods and materials similar or equivalent to those described herein can be used in the practice or testing of embodiments of the present invention, the preferred methods, devices, and materials are now described. All publications mentioned herein are incorporated by reference. Nothing herein is to be construed as an admission that the invention is not entitled to antedate such disclosure by virtue of prior invention.

Embodiments of the present invention are substrates and methods for making such substrates which may be used in the fabrication of photovoltaic cells. The substrate include a thermally stable substrate on which is coated with a wide bandgap semiconductor material. These substrates may be used in the fabrication of monolithic photovoltaic assemblies. For example, the substrates may be further coated with a conductive material, light absorbing semiconductive materials, an insulator, and transparent window material to form photovoltaic devices. The coatings and methods of the present invention provides for monolithic manufacturing of such substrates and also provide for monolithic fabrication of photovoltaic solar cells on these substrates. These substrates can tolerate the high temperature annealing that improves the grain structure and leads to improved efficiency of some light absorbing semiconductor materials used in the manufacture of photovoltaic cells.

The substrate of the present invention includes a thermally stable substrate and a wide band gap semiconductor film on the surface of the thermally stable substrate. The thermally stable substrate may be heated above about 450° C., and preferably above about 550° C. without loss of its mechanical properties. Suitable materials for the thermally stable substrate may include but is not limited to metals or alloys that include metals. Preferably the metallic or other thermally stable substrates are in the form of mechanically flexible foils, sheets, or thin films. Examples of such material include stainless steel, titanium, molybdenum, or alloys including these metals.

One criteria for selecting a stable insulator, which is no change in electrical properties by doping, is to have high band gap energy. Materials that may be used as the insulating material are as Aluminum Nitride (AlN) and Magnesium Oxide (MgO). All of these materials have attractive properties to be considered as insulating materials for the CIGS system and they are stable at high temperatures (>800° C.). AlN has outstanding properties having a band gap of 6.2 eV and a good dielectric constant value at 8.5. AlN has excellent thermal conductivity and is thermally stable up to 800° C. which permits thermal annealing of CIGS. AlN is chemically stable and adheres well as a thin film on metals. The deposited thin film of AlN is generally smooth and will minimize the pinhole defects; the film is pinhole porosity free. The coefficient of thermal expansion (CTE) value of AlN is in between CIGS and SS or Mo and AlN has good mechanical properties as well. Preferably the CTE of the insulating film is within about ±20% of the CTE of the metallic substrate and light absorbing semiconductor material; more preferable the CTE is within about ±10% or less of the CTE of the metallic substrate and light absorbing semiconductor material. These attractive properties make AlN an excellent candidate for the insulation material. Similarly, MgO has favorable properties in terms of band gap values, and are thermally and chemically stable to be also considered as an insulating layer for PV cells.

TABLE 1

| | | | | | CTE, |
|---|---|---|---|---|---|
| | Resistivity, | Dielectric | Band Gap, | Dielectric | 10⁻⁶/ |
| Material | Ω · m | constant | EV | Loss | ° C. |
| AlN | 10¹² | 8.9 | 6.2 | .0001-.001 | 4.6 |
| MgO | 10¹⁰ | 8.2 | 8 | .002-.001 | 12 |
| MgAl₂O₄ | 10¹⁰ | 7.5 | >5 | .003 | 5 |
| Spinel | | | | | |
| Mo | | | | | 5.35-6 |
| Stainless | | | | | 11 |
| Steel | | | | | |
| CIGS | | | | | 9 |

An insulating film is deposited onto the metallic substrate. The insulting material includes but is not limited to dielectrics and wide band gap semiconductors. A wide band gap semiconductor or other electrically insulating dielectric film is deposited onto the thermally stable or metallic substrate. It is preferable that the wide bandgap semiconductor or other insulating material be capable of being heated above about 450° C., and more preferably above about 550° C. without loss of its mechanical or electrical properties. The wide bandgap semiconductor material or other insulating material preferably has a bandgap greater than about 2.0 eV and may include but is not limited to AlN, MgO, SiC and GaN, other metal oxides, and compound semiconductor such as AlInGaN or AlₓGa₁₋ₓN. The wide bandgap semiconductor or other insulator dielectric material is used as an electrically insulating coating on the thermally stable substrate. The wide bandgap semiconductor material adheres to the thermally stable substrate and remains adherent to it even after thermal cycling to temperatures greater than about 450° C. and more preferably greater than about 550° C. This insulating coating on the thermally stable substrate allows high temperature annealing of light absorbing materials like CIGS; the insulting coating may be useful for Cd—Te and Ga—As based solar cells.

It is preferable that the wide bandgap semiconductor film is a continuous film that is pinhole porosity free and without pores, pinholes, voids or other defects. The thickness of the wide bandgap semiconductor material formed or deposited on to the thermally stable substrate should prevent electrically shorting or dielectric breakdown of the wide bandgap semiconductor. Preferably the wide bandgap semiconductor will be insulating even with an applied potential of about 187 volts DC or more and will have a thickness of about 3 microns or less. The pinhole porosity free wide bandgap semiconductor or insulating layer allows electrical isolation of the metallic foil of the thermally stable substrate thereby allowing electrical separation of photovoltaic cells and monolithic construction of modules in series and with appropriate accumulated power. The pinhole free wide bandgap semiconductor or insulating film on the thermally stable foil substrate should withstand the processing temperatures above 450° C., preferably above 550° C., and enable proper light absorbing semiconductor grain structure development that results in high cell efficiencies. One skilled in the art could determine the maximum temperature at which these substrates could be processed by thermally cycling them and then inspecting the films for adhesion to the substrate. The substrates should be thermally stable up to a temperature useful for annealing, reacting, or treating a composition deposited onto it. The particular temperature will depend upon the material and reaction or property to be optimized. For example, the temperature may be one sufficient to increase the grain size of a light absorbing semiconductor composition to maximize its charge generating properties

The insulating material on the metallic substrate preferably has a coefficient of thermal expansion that is similar to that of the thermally stable substrate so that they continue to adhere to each other even after thermal annealing at temperatures greater than about 550° C. This gives solar cells fabricated on such substrates a longer operating life. Besides the thermally stable substrate, this insulating layer is chosen to have a coefficient of thermal expansion (CTE) which is similar to the other constituent materials of the photovolatic cell particularly the conductive molybdenum layer, CIGS, Ga—As, and Cd—Te photoactive layers. Preferably the CTE of the insulating layer is within about ±25% of the CTE of the metallic substrate, the conductive layer, and or the light absorbing semiconductor layer. More preferably the CTE of the insulating layer is within about ±10% of the CTE of the metallic substrate, the conductive layer, and or the light absorbing semiconductor layer.

The insulating or wide band gap semiconductor material may be formed or deposited on the surface of the thermally stable and or metallic substrate by physical vapor deposition or ion assisted physical vapor deposition. All of the thermally stable substrate or areas of the substrate, which may be defined by a mask, may be covered with the wide bandgap semiconductor material. Preferably the thermally stable substrate is first cleaned by ion bombardment.

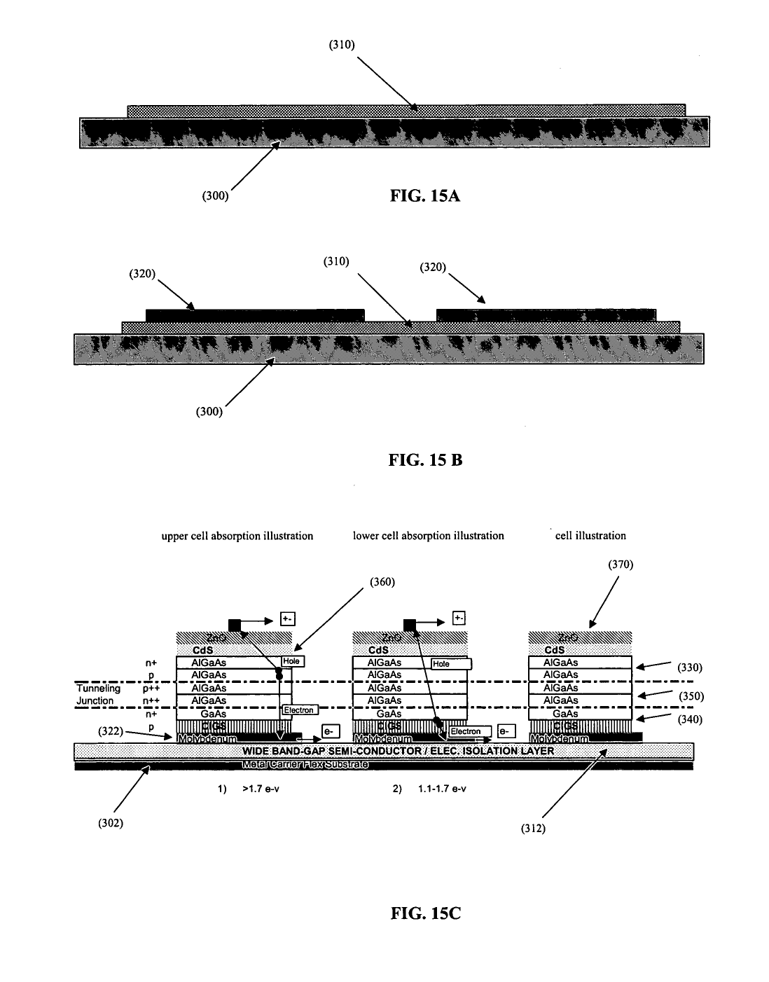

As illustrated in FIG. 15 A, rigid or flexible materials that are stable under semiconductor processing and annealing conditions may be used as substrates (300) and coated with the insulating or wide bandgap semiconductor materials (310) in the embodiments of the present invention. Preferably other layers of materials such as metals or semiconductors (320) are deposited on top of the insulating or wide bandgap semiconductor material layer (310). The substrate (300), and preferably a flexible substrate, are chemically and thermally stable under processing and annealing conditions used in the deposition of the insulating layer (310) like MgO and additional metals or semiconductors (320) such a molybdenum and semiconductor light absorbing material layers such as CIGS. These process condition may include those temperatures, treatment times, and reagent that result in improved properties for the material layer. Thermally stable and flexible substrates materials may include metals, metal alloys, conductive composites which can be bent or rolled easily and which are thermally stable above about 450° C., and preferably above about 500° C. and more preferably above about 550° C. Substrates include but are not limited to foils, sheets, webs and rolled forms of materials that include metals and their alloys which are flexible and thermally stable under conditions used to form solar cells and having CIGS or other copper containing semiconductor light absorbing layers. Preferred materials for substrates include but are not limited to stainless steel, titanium, molybdenum, and aluminum.

The flexible materials may be characterized by having thickness which allows roll to roll coating of the side bandgap semiconductor dielectric materials onto the substrate and the formation of multiple electronic devices, circuits, battery, and photovoltaic cells on the substrate. Preferably the flexible material has a thickness below about 0.007 inches, and can be below about 0.001 inch thick. Most preferably the thickness of the substrate is from about 0.001 inches to about 0.003 inches.

The wide bandgap semiconductor materials may be deposited onto flexible thermally stable substrates such as foils and webs of metals and their alloys to form an adherent film on the substrate even after thermal cycling, annealing, or processing of the substrate and deposited wide bandgap semiconductor material. Thermal cycling, annealing, or processing conditions may include temperature above about 450° C., preferably temperatures above about 500° C. and more preferably temperatures above about 550° C. in an inert gas atmosphere.

Physical vapor deposition, and preferably ion assisted e-beam deposition can be used to deposit the wide bandgap semiconductor material onto the flexible thermally stable substrates. Where the dielectric is a material like MgO, pure MgO (99.99% purity-crystal) can be used for deposition from a copper crucible. For a dielectric like AlN, an aluminum source and nitrogen under reactive deposition conditions may be used.

Deposition condition can vary, however preferred chamber pressure can range from about 10⁻⁶ mbar before and 10⁻⁴ mbar during deposition. In MgO deposition, argon and oxygen can be used, and the argon to oxygen ratio can be about 1:1. Oxygen used in chamber during deposition can be introduced through bleeding via a valve, mass flow controller or orifice. Ion beam and E-beam both can be divergent type and both heating together. Planetrory rotating type holders with the divergent type E-beam and Ion beam can be used to cover substrates present in the working chamber. The distance between substrate and crucible can be varied, as an example the distance can about 20 inches. An 8 KeV electron gun can be used, a potential of about 1 KeV is an example of a potential that can be used for an MgO deposition rate of about 10 Å/sec; the deposition rate can be increased by increasing the potential of the electron gun. A 350 eV ion energy for the ion gun with ion beam currents in the range of about was 20 milli-amp can be used. Substrates can be cleaned by ion gun prior to deposition.

To form photovoltaic cells on the substrates comprising the thermally stable substrate with the wide band gap semiconductor layer on its surface, a thin film of a conductive material may formed or applied to a portion or to selected areas of the wide band gap semiconductor layer. A mask may be used to pattern the deposition of various layers in the photovoltaic cell and preferably in different stages of CIGS and electrode layer deposition. The wide bandgap semiconductor material insulates adjacent areas of the conductive film from one another. The conductive material forms one of the electrodes for the photovoltaic cells and provide electrical contact with one of the light absorbing semiconductor layers of the photovoltaic cell. Preferably the conductive material has a coefficient of thermal expansion similar to that of the wide bandgap semiconductor material so that they continue to adhere to each other even after thermal cycling. The thickness of the conductive film minimizes its electrical resistance for proper function and efficiency of the cell and may range from about 0.7 to about 1 micron in thickness. The conductive films may be made by method known those skilled in the art and may include chemical vapor deposition and physical vapor deposition. Conductive materials may include but are not limited to molybdenum, tungsten, titanium, and conductive alloys.

A first light absorbing semiconductor composition layer is then applied to at least a portion of each conductive film area. The area not coated with the light absorbing semiconductor composition can be used for an electrical connection using a conductor with the other partially coated light absorbing semiconductor conductive film areas on the wide bandgap semiconductor. Preferably the area not coated by the light absorbing semiconductor material is a pad less than about 1 cm² in area.

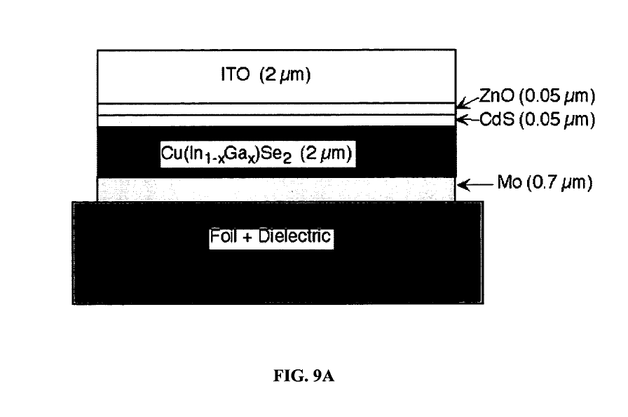

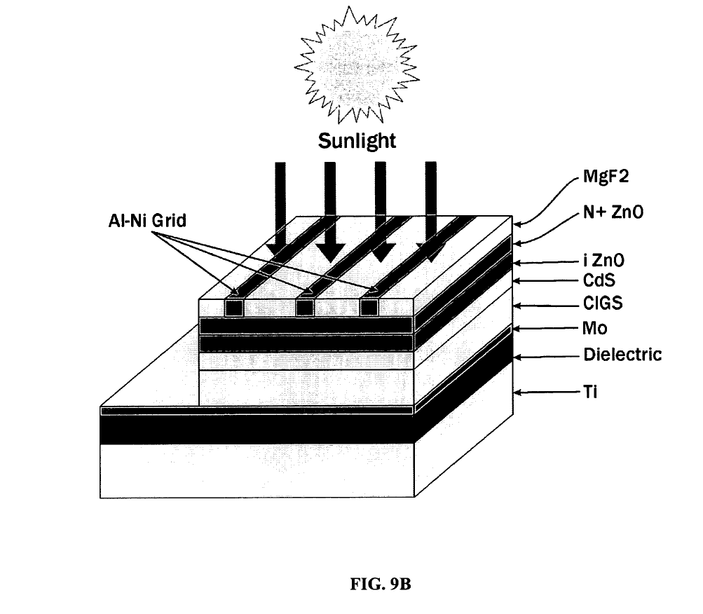

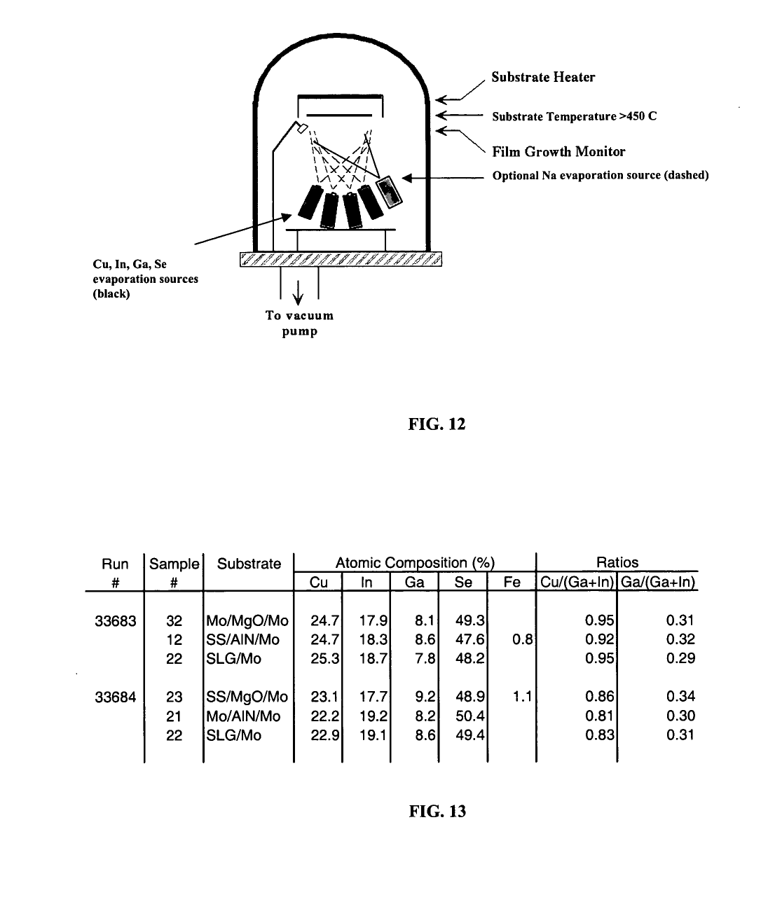

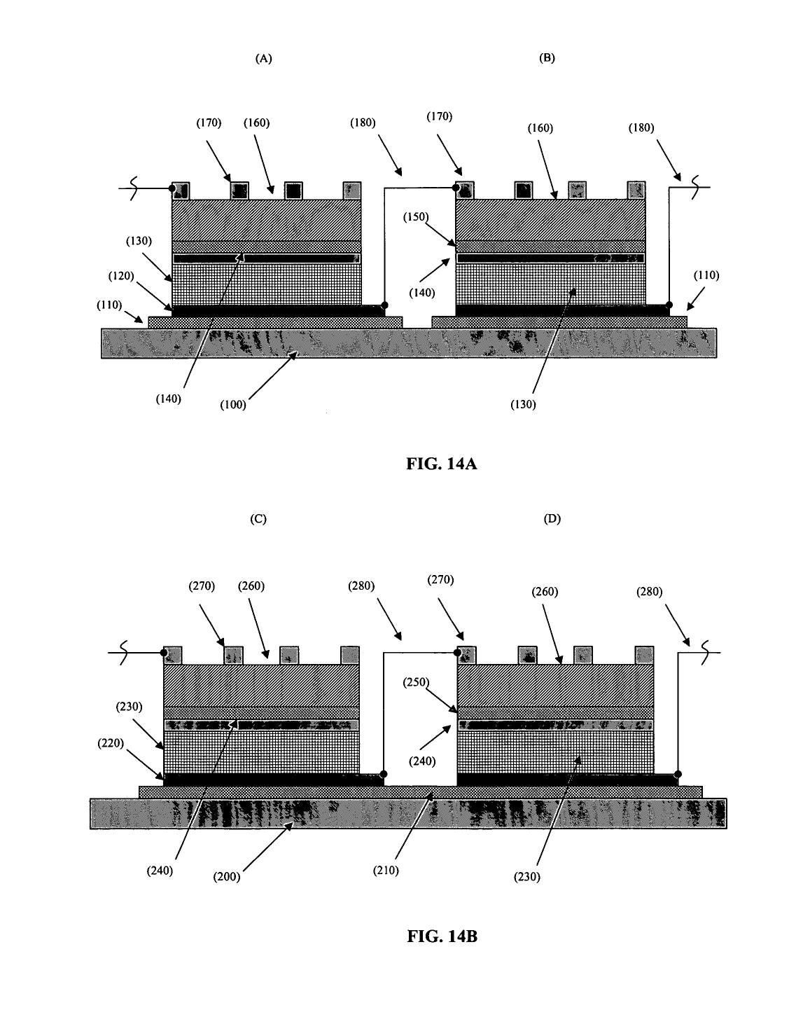

Semiconductors that are light absorbing or photoactive materials are useful in embodiments of the present invention can be deposited onto an electrode 110 in FIG. 14A or electrode 210 in FIG. 14B. The light absorbing material may include but are not limited to semiconductors like CIGS, CdTe, or GaAs, or a-Si. The light absorbing semiconductor compositions can also include compound semiconductors that preferably includes copper. Examples of compound copper containing light absorbing semiconductor compounds include but are not limited to those represented by Cu(In, Ga)Se₂, CIGS, Cu(In₁₋ₓGaₓ)Se₂ where x is chosen so that the Cu/(Ga+In) ratio is between 0.8 and 0.95; CuInSe₂; CuInS₂; or CuGaSe₂. These copper based semiconductor light absorbing materials may be made by thermal evaporation of indium, gallium, copper, sulfur, selenium, and tellurium sources as illustrated in FIG. 12. Optionally a dopant like sodium may also be co-deposited and incorporated into the semiconductor film using a dopant source (shown as an Na evaporation source in FIG. 12). Non-limiting photovoltaic structures that includes a copper containing light absorbing semiconductors layer are shown in FIGS. 9A, 9B, and FIG. 15. The morphology and composition of semiconductor light absorbing layers can be determined using SEM and Energy Dispersive Spectroscopy (EDS). Examples photovoltaics prepared by the inventors where the CIGS composition atomic ratio of Cu/(Ga+In) is between 0.8 and 0.95 are shown in the Table of FIG. 13.

The efficiency for converting light (photons) to electricity (voltage), by the photovoltaic (PV) effect with materials of the present invention include 8.5% for SS/MgO substrates and 8.2% efficiency for Cr-coated SS/MgO substrates both having a Cu(In, Ga)Se₂ semiconductor light absorbing layer deposited on the flexible and thermally stable substrates coated with a wide bandgap semiconductor of the present invention. While thermal annealing can lead to increase grain size and improved efficiencies in the light absorbing semiconductor layer, other methods exist, like the incorporation of sodium as a dopant into the Cu(In, Ga)Se₂ semiconductor light absorbing layer. Without wishing to be bound by theory, it is believed that the dopant can improve the efficiency by increasing grain size, passivating grain boundary effects, increasing effective acceptor concentration in the semiconductor light absorbing layer. Sodium may be added during vapor deposition of the semiconductor light absorbing layer as illustrated in FIG. 12 where a sodium source, for example but not limited to sodium metal. Na₂S, or a sodium salt like NaF, is co-evaporated or sublimed onto the substrate and incorporated into the film. The incorporation of sodium into the film is expected to raise efficiency above 8.5% and preferably as high as 12% or more. The sodium produced during the vapor deposition step can be in the low atom percent range, preferably a concentration of about 1-2 atom percent. This amount can be modified outside of this range to achieve the desired deposition rate and concentration in the light absorbing semiconductor film, other atom percents for the dopant could be determined by correlating dopant amount and cell efficiency.

The light absorbing semiconductor layer is preferably annealed a temperature sufficient to more fully develop and increase the grain size of the composition in the layer. The annealing process may occur with a flow of a chemically suitable gas like helium or in a reduced pressure environment. The annealing temperature as illustrated for the substrate or flexible thermally stable substrate in the reactor in FIG. 12 may be greater than about 450° C. and is preferably about 550° C. or more. The annealing time may be determine by one skilled in the art based upon the efficiency of photovoltaic cells made and the time and annealing temperature.

As shown in FIG. 14A, the photovoltaic cell further comprise a buffer layer (140) which can be but is not limited to CdS (FIG. 9A), In(S,OH), or ZnSe. The buffer layer may be formed on the surface of light absorbing layer using a chemical bath or by other method known to those skilled in the art. This buffer layer and the light absorbing semiconducting composition form the photovoltaic junction. The buffer layer may have a non-limiting thickness of about 30-50 nm. An optically transparent insulating layer (150) and (160) or wide bandgap semiconductor material such as but not limited to ZnO (150), ZnO:Al, ITO (160) can used to over coat the buffer semiconductor layer and may be deposited by sputtering. Metal contacts as a grid are provided over the ZnO layer (150) or ITO layer (160) using for example Ni/Al, Al, Ag, In, or Au which may be deposited by sputtering or e-beam evaporation. Antireflective coating of MgF₂ may be provided to increase the efficiency of the cell. An encapsulate material may be used to protect the cells.

The coatings in FIG. 9 are one example of a typical solar cell. Other layers may be applied in place of, or in addition to this particular construction of photovoltaic cell. These layers may be applied by various Physical Vapor Deposition (PVD) techniques, such as sputtering, electron beam, ion-bombardment, or some combination of these. For example, the semiconductor material might be applied by ion-beam assisted sputtering, while the other coatings may be deposited in the following manner: sputtering technology for molybdenum, CIGS, ZnO; Chemical Bath Deposition (CBD) for CdS; and, the metal contact material is applied by either direct write technology, screen printing of highly conductive ink, by similar masked sputter deposition, laser deposition, or by decal. E-Beam processing might replace sputtering as the method of PVD. Ion assisted e-beam or ion assisted PVD can be used to deposit the dielectric coating on the flexible thermally stable substrate.

Monolithic formation of a plurality of photovoltaic cells may be achieved using the methods and substrate of the present invention. The photovoltaic cells being fabricated on electrically conductive areas on the wide bandgap semiconductor. The photovoltaic cell on the electrically conductive area being electrically connected in series with each other. The electrical connection being made from the electrically conductive area of one cell to the wire grid on an adjacent cell. For example, FIG. 14B illustrates substantially similar photovoltaic cells (C) and (D) (additional cells not shown) on a flexible thermally stable substrate (200) that can be stainless steel, titanium, molybdenum, aluminum, or alloys these metals. For clarity not all layers on each cell (C) and (D) are labeled, however in a monolithic structure a layer of a wide bandgap semiconductor (210) is deposited for example by PVD or ion assisted PVD on portions of the substrate (200). The wide bandgap semiconductor preferably has a bandgap energy above 2 eV, and more preferably above about 5 eV and may include but is not limited to materials listed in Table 1. Each cell (C) and (D) includes an electrode (220) which may be a conductive material deposited as pads on portions of the dielectric layer (210) such as but not limited to Mo, Au, or Ta, and which provides a contact for connection to a conductor (280) for electrical connection to the cell. The cells (C) and (C) include a semiconductor layer (230) which is preferably a light absorbing material such as but not limited to CIGS, GaAs, or CdTe, and a buffer layer (240) on the semiconductor layer (230) such as but not limted to CdS or ZnSe. The cells (C) and (D) can further include conductive semi-transparent oxide layers (250) and (260) with a non-limiting thickness of from about 0.05 microns to about 2 microns. Electrical connection to the cell can further include a metal grid (270) with non-limiting thickness of about 1-3 microns of metals like Ni, Al, In, or Ag deposited by vacuum evaporation or sputtering. Cells on the substrate (200) can be interconnected, preferably in series, for example the cells (C) and (D), by a conductor (280) electrically connecting the grid (270) of one cell with the electrode (220) of another cell.

As illustrated in FIG. 15 the tandem solar cell or multijunction device can include an upper solar cell (330) with p doped AlGaAs absorption layer, a lower solar cell (340) having a p doped CIGS absorption layer, and an intermediate buffer layer (350) having a tunnel junction with n++ AlGaAs and p++ AlGaAs layers. The high band gap energy light of the incident solar spectrum light is absorbed by the upper solar cell while the low band gap energy light having passed through the upper solar cell is absorbed by the lower solar cell. The buffer layer is a semiconductor layer having a larger band gap energy than the upper solar cell to permits longer wavelength light to pass through to the lower solar cell. Preferably there is a crystalline lattice match with the upper solar cell, and a the buffer layer.

The photovoltaic cells prepared in the practice of the present invention may be made using vacuum process techniques such a physical vapor deposition and evaporation as well as non vacuum processing techniques such as sintering of deposited powders, thermally annealing spray coatings, electrochemical deposition or materials deposited in the form of inks or other such techniques as would be known to those skilled in the art. The substrates of the present invention may use high temperature CIGS processing in with vacuum or non-vacuum processed CIGS coatings.

### EXAMPLE 1

This example illustrates the deposition process for a pinhole porosity free insulated film on a metallic substrate for use in a thin film solar cell such as CIGS.

The process sequence utilizes metal foils, such as Molybdenum, Titanium, or Stainless Steel at thickness levels that can vary from 0.003 to 0.007 inches as thermally stable substrates.

The foil was surface cleaned by ion bombardment followed by deposition of thin film wide bandgap semiconductor materials such as Aluminum Nitride (AlN) or Magnesium Oxide (MgO), using ion assisted physical vapor deposition. The wide bandgap semiconductor films had a thickness in the range of thickness from under 1 micron up to 3 or more microns, typically about 2.5 microns.

Standard adhesive peel-off test (MIL-STD-13508) and 180° bend test were performed on the deposited wide bandgap semiconductor layer to successfully demonstrate the adhesion of the insulated films to the metal substrate.

Thermal cycling was carried out on these deposited films at selected temperatures between 550° C. to 25° C. and each temperature was held for 30 minutes. The results show excellent thermal stability of the deposited wide bandgap semiconductor materials.

The pinhole porosity of the films and dielectric integrity of the insulated films were measured by applying DC voltage (up to 200 volts) between metal electrodes (deposited on insulated film for pinhole porosity testing) on the insulated film and metallic substrates.

Characterization of the films by XRD, SEM and EDAX were conducted on the insulated materials at different stages.

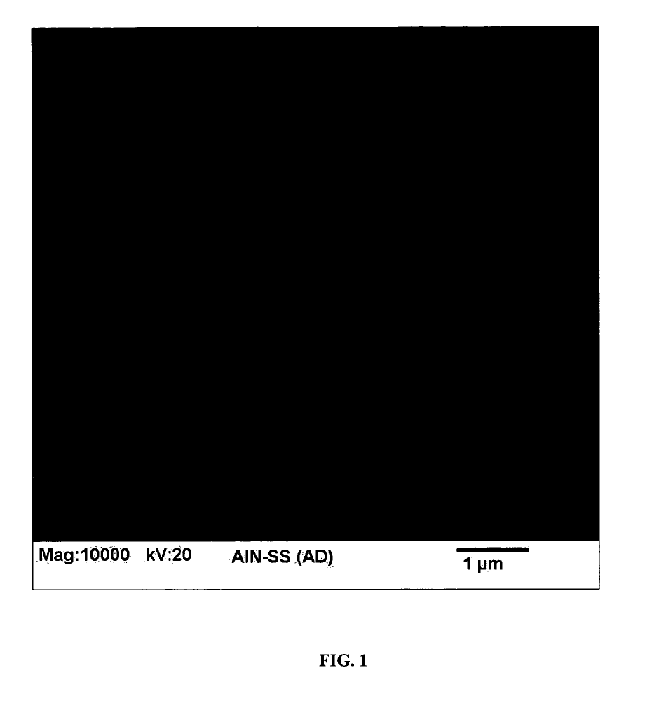

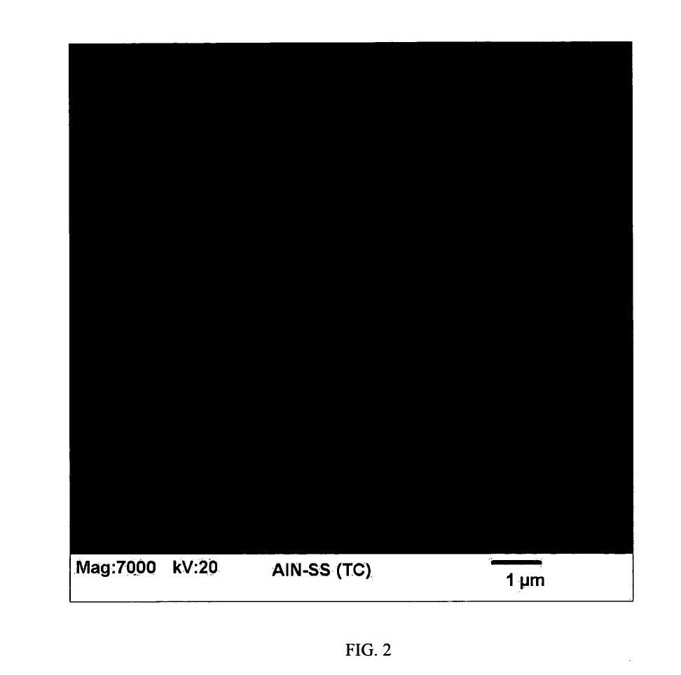

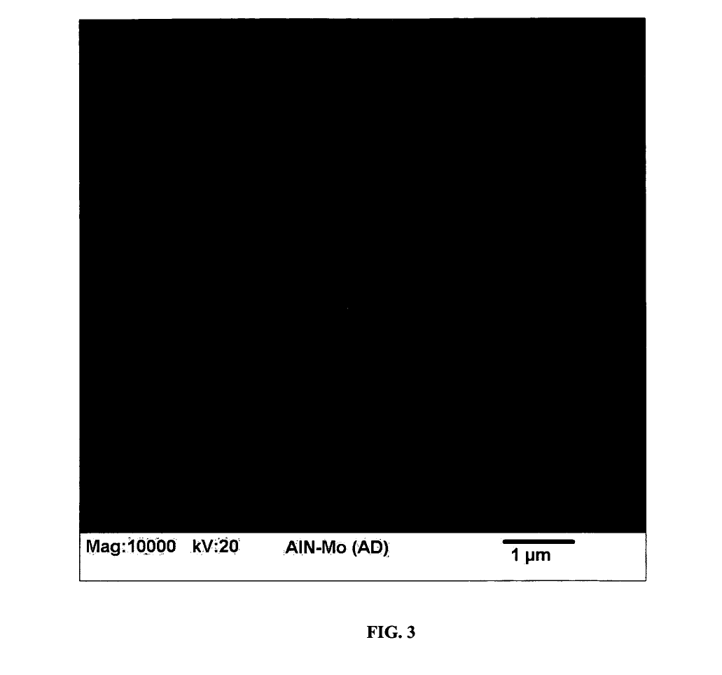

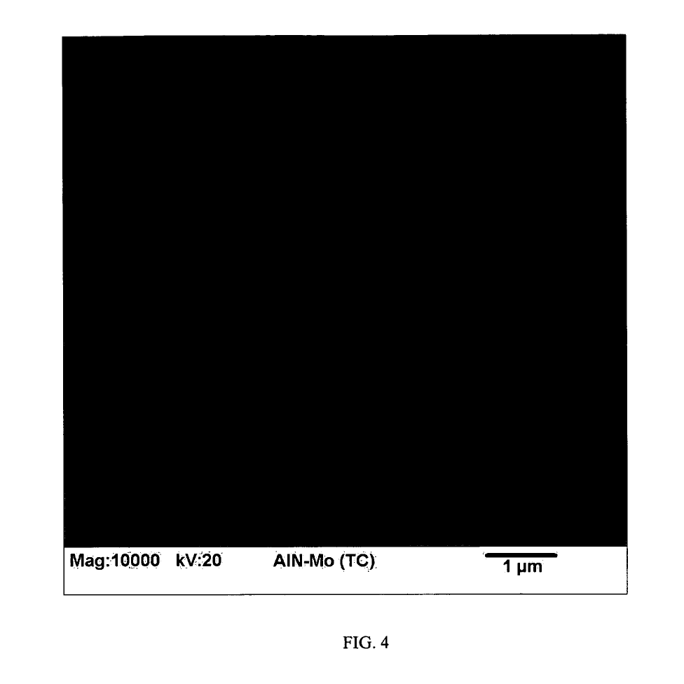

The microstructures of as-deposited (FIG. 1) and thermally cycled (FIG. 2) AlN on stainless steel foil indicate that films are smooth and intact after thermal cycling. Similar behavior for AlN on Mo foil was observed as well as shown in FIGS. 3 and 4 respectively.

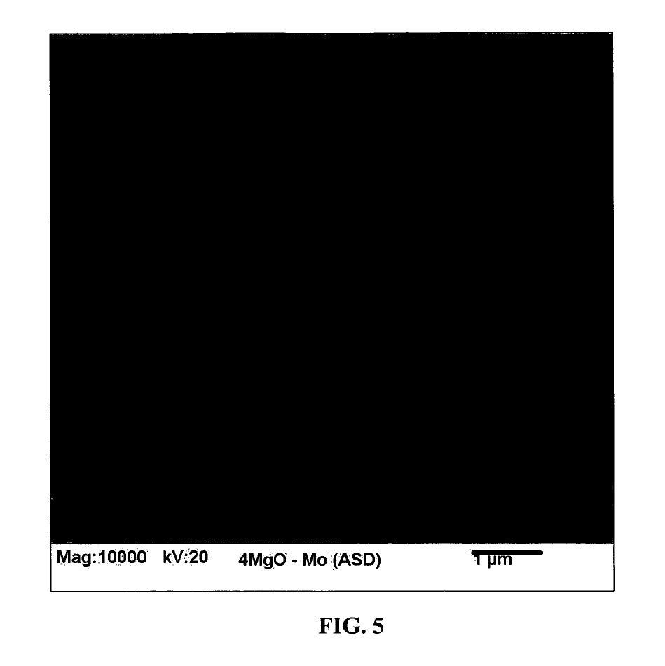

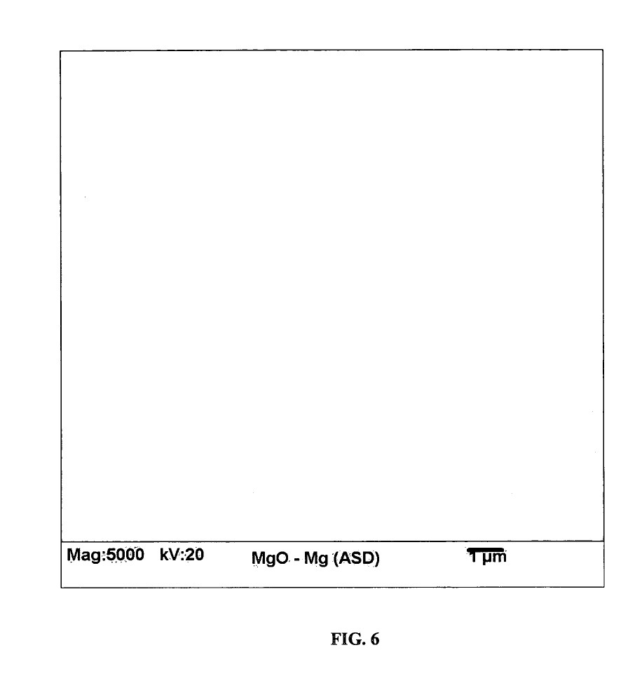

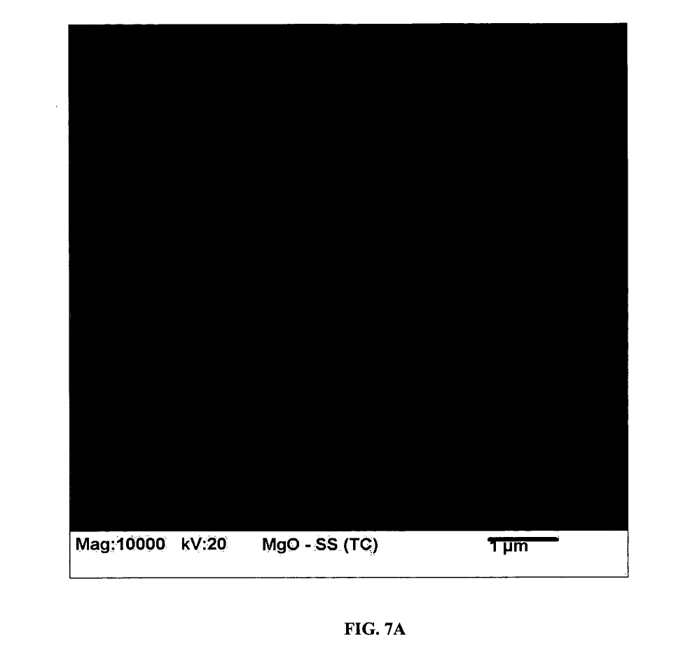

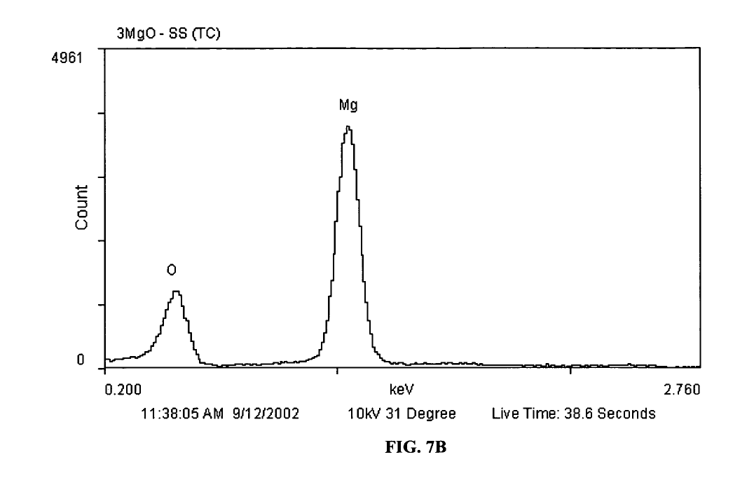

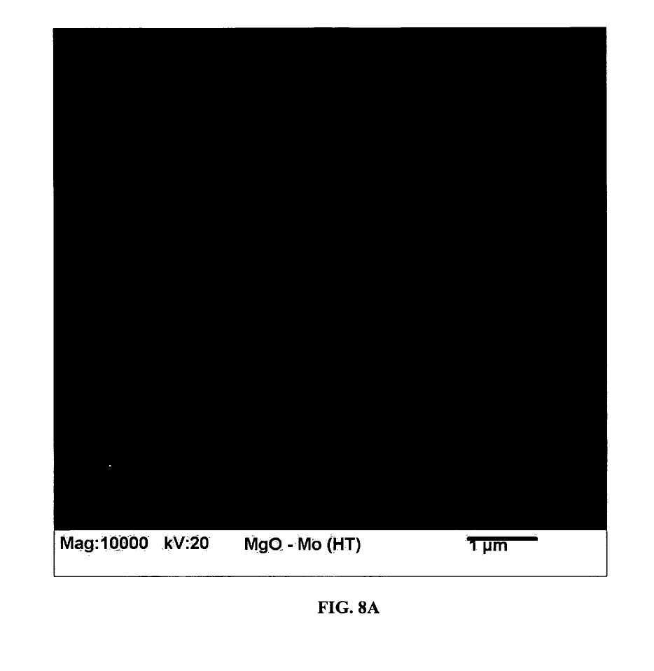

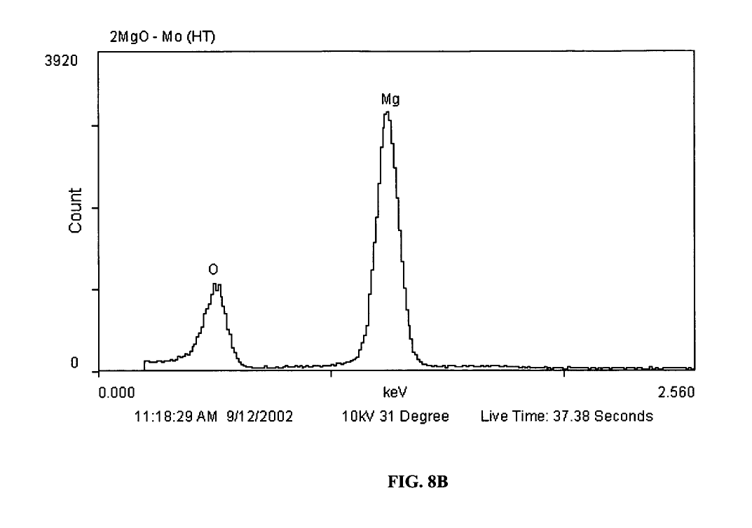

MgO films deposited on stainless steel and Mo foil also shows the smooth surface as depicted in FIGS. 5 and 6 respectively. The MgO films on both SS and Mo substrates were stable after thermal cycling and also annealing as shown in FIGS. 7 and 8 respectively.

All the samples passed the scotch tape test and bending test for adhesion of the wide bandgap semiconductor films to the thermally stable stainless steel and molybdenum substrates. The results indicate that these insulating films are sufficiently adherent to the substrates.

After the electrical test of the AlN and MgO layers, (results shown in Tables 2 and 3) show no pinhole porosity in either the as-deposited or thermally cycled condition for both SS and Mo foils and the films did not fail even after applying 187 DC voltage.

TABLE 2
Pinhole porosity testing results of AlN deposited film

| | 2.5 μm AlN | 2.5 μm AlN | 2.5 μm AlN | 2.5 μm AlN |
|---|---|---|---|---|
| | on SS (AD) | on SS (TC) | on Mo (AD) | on Mo (TC) |
| Pinhole | 100 V-pass | 100 V-pass | 100 V-pass | 100 V-pass |
| Porosity | Did not fail | Did not fail | Did not fail | Did not fail |
| testing | even at | even at | even at | even at 187 volt |
| | 187 volt | 187 volt | 187 volt | |

### EXAMPLE 2

MgO and AlN insulated films were deposited separately on Stainless steel (SS) and Molybdenum foil (Mo). Ion assisted Physical Vapor Deposition technique was used to obtain pinhole porosity free film. Before depositing the film, the metallic substrates such as Mo and SS were cleaned according to the following steps. Initially, they were ultrasonically cleaned using DI water for 15 minutes and then dipped and rinsed in isopropyl alcohol three times followed by cleaning with blowing nitrogen. Before final deposition, the foil was cleaned by ion beam under a vacuum of 2×10⁻⁴ millibar using argon beam for 20 minutes. Insulated film was deposited on the clean foil using Reactive Ion Beam Assisted Vapor Phase deposition technique. AlN and MgO insulated films were deposited separately on Mo and SS foil respectively. Nitrogen and Oxygen gas were used for reactive deposition for AlN and MgO films respectively. Electron-Beam of 1 eV was used for deposition and 250-350 eV energy Ion was used for packing the deposited film to obtain pinhole porosity free film. The deposition rate was kept to about 10 Å/sec and was monitored by quartz sensor. The preferred film thickness of the deposited film is about 2.5 microns.

TABLE 3
Pinhole porosity testing results of MgO deposited film

| | 2.5 μm MgO | 2.5 μm MgO | 2.5 μm MgO | 2.5 μm MgO |
|---|---|---|---|---|
| | on SS (AD) | on SS (TC) | on Mo (AD) | on Mo (TC) |
| Pinhole | 100 V-pass | 100 V-pass | 100 V-pass | 100 V-pass |
| Porosity | (Tested at | Did not fail | Did not fail | Did not fail |
| testing | Aerospace) | even at | even at | even at 187 volt |
| | | 187 volt | 187 volt | |

### EXAMPLE 3

In this prophetic example, the substrates including the thermally stable substrate coated with a wide band gap semiconductor is use to make an array of monolithically integrated solar cells. A void free non-porous insulating layer on metallic substrates may be made in a continuous roll-to-roll process selectively depositing a series of layers in geometries such that the photovoltaic cells are produced aligned in modules, which can be further processed to interconnect the electrodes. This process of producing the photovoltaic cells and the modules at the same time is known as monolithic integration.

The process sequence utilizes metal foils, such as aluminum, Molybdenum, Titanium, or Stainless Steel as a thermally stable substrate at thickness levels that can vary from less than about 0.001 to about 0.007 inches (25-200 microns). The foil surface can be cleaned by ion bombardment and then a thin film wide bandgap semiconductor material such as Aluminum Nitride (AlN) or Magnesium Oxide (MgO), deposited onto the foil using a physical vapor deposition processes, such as, e-beam evaporation, physical vapor deposition, and physical vapor deposition with or without ion-assist. The pinhole free and void free wide bandgap semiconductor material on the foil may have a thickness in the range from about 1 micron up to 3 or more microns, preferably 0.7 to 2.5 microns.

The pinhole porosity free wide bandgap semiconductor layer is deposited on the metal foil on across the entire surface. This provides a dielectric and electrically isolating layer upon which the cells are produced. The subsequent layers including molybdenum conductive layer, light absorbing semiconductor photoactive layer copper indium gallium di-selinide, CdS buffer layer, and ZnO window layer are applied to only selective areas of the geometry of the surface of the wide bandgap semiconducting layer with a mask to prevent material deposit in unwanted areas. Alternatively, these layers may be applied to the full surface and then the areas not required for cell functionality can be ablated by laser scribing or removed by other mechanical means.

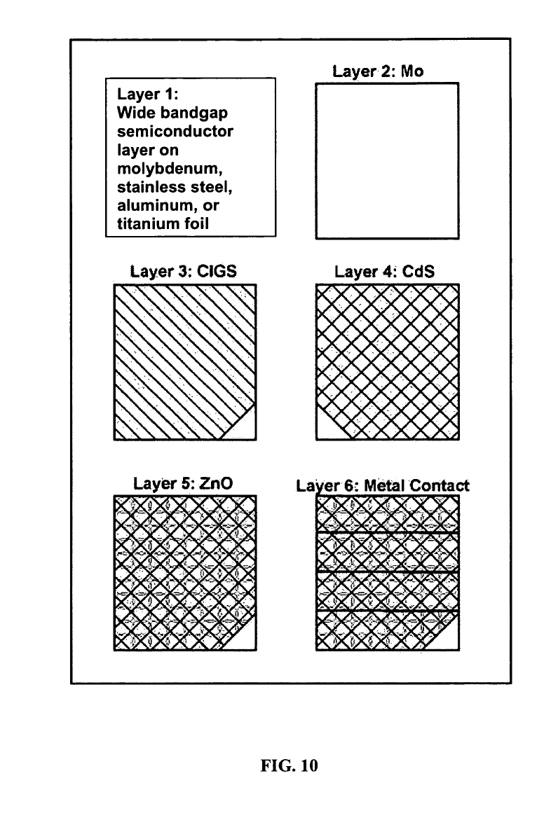

FIG. 10 is a schematic of illustrating the making of photovoltaic solar cells. Following the deposition of the wide bandgap semiconducting layer on the foil, molybdenum metal is deposited. CIGS is then deposited over most of the molybdenum layer. A small portion of the molybdenum is not covered to allow for electrical connection. On the CIGS, cadmium sulfide is deposited by chemical bath deposition. The next layer is ZnO, and strips of metal for electrical contact follow it.

The metal conducting layer of the cell, the molybdenum, requires an area exposed to create the ability for electrical contact between the negative and positive electrodes of each solar cell. At the end of the process the modules are functional and only require a mechanism to complete the electrical circuit and a suitable mechanical frame to hold the module.

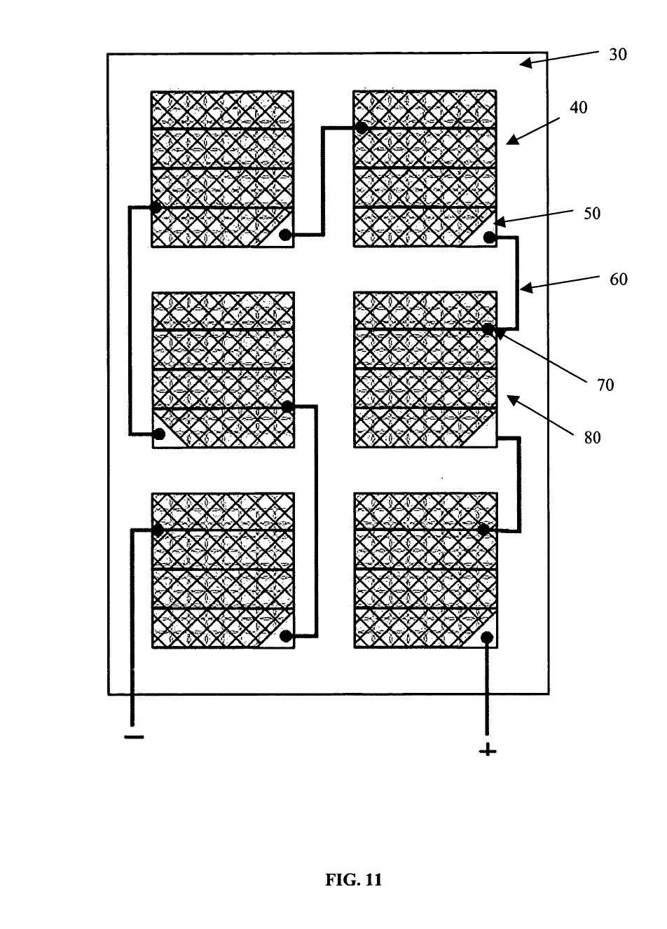

FIG. 11 is an example of a module comprised of 6 solar cells which are electrically connected in series. The geometry of the cell is shown as rectangular, but it could be circular, square, or another geometry.

### EXAMPLE 4

This prophetic example illustrates formation of a multijunction photovoltaic cell on a flexible thermally stable substrate having an adherent wide bandgap semiconductor material deposited on a portion of the substrate. Integration of two junction solar cells with high efficiency can be used for low cost manufacturing of monolithically integrated modules.

Multiple junction cells have been realized in lattice matched crystalline materials systems. Fabrication of photovoltaic cells on flexible substrates such as polyimide or metal foil is attractive for low cost, light weight photovoltaic arrays. Given the efficiency achieved in small CIGS structures, and the fact that higher band gap compositions are available, the Cu(InAlGa)(SeS) system could provide a base for building multiple junctions on flexible substrates.

A multijunction cell may be made by depositing for example polycrystalline III-V materials or other high band gap absorbing materials in the top cell. Combination with other subcells in a multijunction device using the method and material described herein, can be used to offset decreased efficiency of polycrystalline III-V materials and achieve significant gains in efficiency. It has been demonstrated on a small scale that single junction polycrystalline GaAs cells can achieve efficiencies of 20%, provided that grain boundaries are sufficiently passivated and that grain sizes are 20 microns or larger. The other advantage of this materials system is that it provides a clear route to a triple junction cell. A CIGS-AlGaAs based or CIGS-InGaP based tandem cell can be used to fabricate a triple junction CIGS-GaAs-InGaP cell with even higher efficiency. InGaP is the dominant high band gap material in crystalline multijunction cells; AlGaAs may be used to reduce mitigation. The inclusion of AlGaAs also ensures the inclusion of GaAs, a necessary component of a possible triple junction structure.

The tandem cell may be made by growing large grain (50 μm) InGaP or AlₓGa₁₋ₓAs (0<x<0.3) on metallic foil substrates. This can be made using low temperature nanoparticle precursors on metal foil followed by annealing, laser zone annealing or laser heat treatment to produce large grain InGaP and AlGaAs. MOCVD growth of the same structures can also be used followed by the same annealing procedure to increase grain size in the polycrystalline material.

Modeling of dual junction devices based on a CIGS bottom cell shows that one such structure would consist of a 1.7 eV top cell with a 1.1 eV bottom cell. A tandem cell may be made by combining the material system for top cell, bottom cell and tunnel junction based on the results. The selection can be guided by modeling efforts using PC-1D or similar software to simulate the operation of the tandem cell. The effect of finite transmission of sub-bandgap light will be included in the model. Based on device testing results, cell materials and process conditions may be optimized to produce cells having the highest device efficiency.

This example illustrates that flexible and thermally stable metal containing substrates coated with a wide bandgap semiconductor dielectric like MgO or AlN could be used as a substrate for tandem solar cells the incorporate a CIGS layer.

### EXAMPLE 5

This example illustrates the deposited insulating films on 0.003-inch thick molybdenum (Mo), titanium (Ti), Cr coated SS, and 434 stainless steel SS foil. To detect pinhole porosity, a stainless steel mask was designed and fabricated having 3 mm hole diameters separated by 2 mm.

Before deposition, the foils were cut into 40 cm×25 cm rectangular size and subsequently cleaned as described in the following steps. Initially, the foil was ultrasonically cleaned using DI water for 15 minutes and then dipped and rinsed in isopropyl alcohol three times followed by cleaning with blowing nitrogen. Before final deposition, the foil was cleaned by ion beam under a vacuum of 2×10⁻⁴ mili-bar using argon beam for 15 minutes using a predetermined eV value.

Insulating film was deposited on the clean foil using a reactive ion beam assisted vapor phase deposition technique. AlN insulated films were deposited separately on Mo, SS, Cr coated SS and Ti foil respectively. Base pressure inside the deposition chamber was 2×10⁻⁶ mbars prior to growth. During AlN deposition argon/nitrogen gas was used and pressure during growth process was 2×10⁻⁶ mbars, and the growth rate was 8 Angstroms/sec. Deposition temperatures for AlN was 250° C.

To measure the thickness of the films, glass substrates were used. The thickness of the films and surface roughness of the foils were measured by Alphastep-100 profilometer. A standard adhesive peel-off test (MIL-STD-13508) and 180° bend test were performed on the deposited layer to find the adhesiveness.

Aluminum electrodes of 3 mm diameter were also deposited through a stainless steel mask on AlN layers for detecting pinhole porosity. 250 eV energy was used during deposition. Further, a thermal cycling experiment was carried out of the AlN deposited substrates. For thermal cycling, the selected temperatures were 550° C. to 25° C. and at each temperature the sample was held for 30 minutes. Two cycles were used for the thermal cycling experiment and the test was carried out in argon atmosphere. The pinhole porosity of the as-deposited and thermally cycled films and dielectric integrity were tested by applying DC voltage (187 volt) starting from 10 volts and gradually increased to 187 volts between the top Al electrodes and the substrates. All 24 Al-electrode spots on the insulated layers were tested for pinhole porosity. Scanning electron microscopy (SEM) and EDAX of these as deposited (AD) and thermally cycled (HT) films were also performed.

The microstructures of AlN coating on straight SS were measured by SEM. From SEM photographs of AlN coated straight SS, it is noticed that films show the smooth coating and is similar to AlN coatings on Cr coated SS substrate. The coatings are intact and shows similar in nature for both as-deposited and thermally cycled conditions. SEM of the as-deposited and thermally cycled AlN films on Ti and its EDAX spectrum shows the representative peaks of AlN film on Ti substrate and indicates the coating is smooth and uniform in as-deposited and also after thermal cycling. All the coatings show fine crystalline structure in SEM microstructures. The cross section of the AlN films in all conditions (as-deposited and thermally cycled) shows uniform and adherent films on Ti foil substrate. There are no peelings off of the film from either Ti or Mo substrate as well even after thermal cycling. The EDAX spectrum of the coating indicated the presence of AlN film in Ti substrate after thermal cycling and this spectra is identical to its as-deposited spectra (not shown in this report ). The EDAX spectra of AlN coated samples for all substrates are identical for all conditions. All the samples passed the scotch tape test and bending test. The results indicate that AlN films are sufficiently adherent to the substrates. In case of electrical test, of the AlN layer test patterns show no pinhole porosity in as deposited as well as thermally cycled conditions for all those four substrates. Not a single point shows any electrical breakdown during voltage increase from 10 volt to 187 volts while pinhole porosity testing.

### EXAMPLE 6

This example illustrates roll to roll web coated substrates. An MgO coating was deposited using ion beam assisted deposition (IBAD) on Stainless steel (SS) and Ti foils. For coating, foil was mounted on a drum approximately 18″ in diameter (˜4.5 ft length per run) and rotated continuously through the ion and coating flux. Before deposition, the foils were cut into suitable length and subsequently cleaned using isopropyl alcohol three times followed by cleaning with blowing nitrogen. Before final deposition, the foil was cleaned by ion beam under a vacuum of 2×10⁻⁵ mili-bar using argon beam for 15 minutes using a predetermined e V value.

Insulating MgO film was deposited on the clean foil using a Reactive Ion Beam Assisted Vapor Phase deposition technique. The deposition chamber was evacuated by using a large diffusion-pumped to the level of 1×10⁻⁵ Torr. During deposition argon/oxygen gas was used and pressure during growth process was 1×10⁻⁴ Torr, and growth rate was varied in different run. One of the deposition (expt#6) was performed without Ion beam assisted (without IBAD). A 40 cc, 4 pocket E-beam hearth and an 8″ linear ion source was used. Coating thickness was measured by Stylus profilometry. A simple break down voltage of the dielectric coating was randomly measured. A standard adhesive peel-off test (MIL-STD-13508) and 180° bend test were performed on the deposited layer to find the adhesiveness of the coatings on the substrate.

SEM analysis and dielectric testing were performed. Aluminum electrodes of 3 mm diameter (24 number per specimen) were also deposited through a stainless steel mask on MgO layers for detecting pinhole porosity. In addition, continuous Al coating over an area of 25 mm×15 mm on some of the MgO layers were also deposited for dielectric testing. The pinhole porosity of the as-deposited films and dielectric integrity were tested by applying DC voltage (187 volt) starting from 10 volts to gradually increases to 187 volts between the top Al-electrodes and the substrates. All 24 Al-electrodes spots on the insulated layers were tested for detecting pinhole porosity.

Expt.# 1, Substrate SS and Ti foil, Width of the foil, approx. 4.75″, length approx. 18″. Deposition rate=10 Å/sec, Coating thickness=2.8 μm. Surface appearance of the coating=It is not very smooth, sever arcing is observed.

Expt.# 2, Substrate SS and Ti foil, Width of the foil, approx. 4.75″, length approx. 18″. Deposition rate=10 Å/sec, Coating thickness=2.5 μm. Surface appearance of the coating=It is not very smooth, arcing is observed.

Expt.# 3, Substrate SS, Width of the foil, approx. 12″, length approx. 18″ Deposition rate=10 Å/sec, Coating thickness=3 μm. Surface appearance of the coating=It is smooth, no arcing is observed.

Expt.# 4, Substrate SS and Ti foil, Width of the foil, approx. 4.75″, length approx. 18″ Deposition rate=45 Å/sec, Coating thickness=2 μm. Surface appearance of the coating=It is smooth, less arcing is observed.

Expt.# 5, Substrate SS and Ti foil, Width of the foil, approx. 4.75″, length approx. 18″ And also some Al-foil. Deposition rate=100 Å/sec, Coating thickness=2 μm; Surface appearance of the coating=It is smooth, less arcing is observed.

Expt# 6, Substrate SS and Ti foil, Width of the foil, approx. 4.75″, length approx. 18″ But without Ion assisted. Deposition rate=50 Å/sec, Coating thickness=2 μm; dielectric testing randomly over the coating surfaces showed that it could withstand upto 200 volt.

The results show roll to roll coating of a wide bandgap semiconductor on a flexible and thermally stable substrate. The films can be deposited at various rates and thickness by physical vapor deposition with ion assist or without ion assist.

### EXAMPLE 7

This example illustrates a process and conditions for the deposition of dielectric materials on various flexible and thermally stable substrate materials. Approximately 3.5 microns of AlN or MgO could be deposited on 0.003 inch thick molybdenum (Mo), titanium (Ti), Cr coated SS and 434 Stainless steel (SS) foils under these conditions.

Before deposition, the foils were cut into 40 cm×25 cm size and cleaned according to the following steps. Initially, it was ultrasonically cleaned using DI water for 15 minutes and then dipped and rinsed in isopropyl alcohol three times followed by cleaning with blowing nitrogen. Before final deposition, the foil was cleaned by ion beam under a vacuum of 2×10⁻⁴ mili-bar using argon beam for 15 minutes using a predetermined eV value. Insulating film was deposited on the clean foil using Reactive Ion Beam Assisted Vapor Phase deposition technique. MgO and AlN insulated films were deposited separately on Mo, SS, Cr coated SS and Ti foil respectively. Base pressure inside the deposition chamber was 2×10⁻⁶ mbars prior to growth. During AlN deposition argon/nitrogen gas was used and pressure during growth process was 2×10⁻⁴ mbars, and growth rate was 8 Angstroms/sec. For MgO oxide growth, Argon/Oxygen gas was used and growth rate was 10 Angstroms/sec.

Deposition temperature for both AlN and MgO was 250° C. To measure the thickness of the films, glass substrates were used. The thickness of the films and surface roughness of the foils were measured by Alphastep-100 profilometer. Standard adhesive peel-off test (MIL-STD-13508) and 180° bend test were performed on the deposited layer to find the adhesiveness. Two sets of samples were prepared for each condition. Aluminum electrodes of 3 mm diameter were also deposited through a stainless steel mask on AlN and MgO layers for detecting pinhole porosity. 250 eV energy was used during deposition. Further, a thermal cycling experiment was carried out on the MgO and AlN deposited substrates. For thermal cycling, the selected temperatures were 550° C. to 25° C. and at each temperature the sample was held for 30 minutes. Two cycles were used for the thermal cycling experiment and the test was carried out in argon atmosphere. The pinhole porosity of the as-deposited and thermally cycled films and dielectric integrity were tested by applying DC voltage (187 volt) starting from 10 volts to gradually increases to 187 volts between the top Al-electrodes and the substrates. All 24 Al-electrodes spots on the insulated layers were tested for detecting pinhole porosity.

### EXAMPLE 8

This example illustrates the deposition of CIGS onto flexible substrates coated with about 3 microns of a dielectric to form operating cells. Metal substrates with dielectric layer and soda-lime glass (SLG) substrates were coated with layers to form the cells.

The cells on completed substrates were tested for open-circuit voltage Voc: and short-circuit current Jsc (under Air Mass 1.5 Global light, 100 mW/cm², “1 sun”), using a Keithley 238 source measure unit. An additional current measurement at −1 V bias J_{-1V} gives information on the shunt conductance G_{SH} of the cell. In a first approximation G_{SH}=(J_{sc}-J_{-1V})/1V.

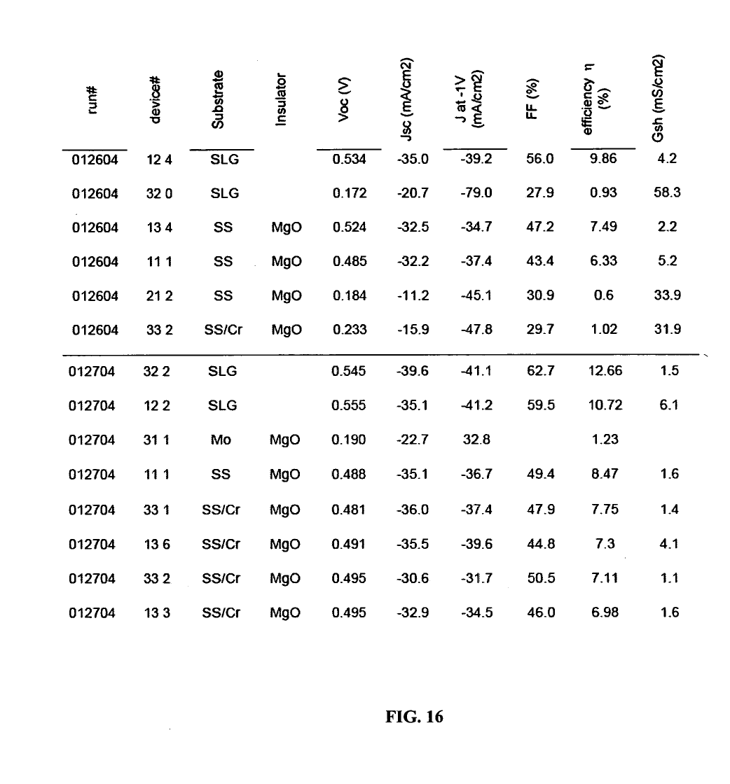

One of the cells (usually the one with the highest V_{OC}*J_{SC}) was subject to a current-voltage scan, which yields the fill factor FF and conversion efficiency η. Representative data from prepared cells are summarized in the Table in FIG. 16. The efficiency of a cell prepared on a TilMgO substrate had Voc=0.488 V, Jsc=35.1 mA/cm² and a fill factor of 49.4% and 8.5% efficiency (012704-11-1).

The results show that a variety of flexible thermally stable substrates can be coated with a dielectric and used to form functioning solar cells.

### EXAMPLE 9

This examples shows the formation of CIGS solar cells on substrates coated with dielectric from a roll to roll coating process. An MgO coating 2-2.5 microns thick was deposited using ion beam assisted deposition (IBAD) on Stainless steel (SS) and Ti foils. For coating experiment, foil was mounted on a drum approximately 18″ in diameter (−4.5 ft length per run) and rotated continuously through the ion and coating flux. CIGS devices were fabricated on some of the roll-to-roll web coated substrates. Metal substrates with dielectric layer and soda-lime glass (SLG) substrates were coated with layers to form the cells.

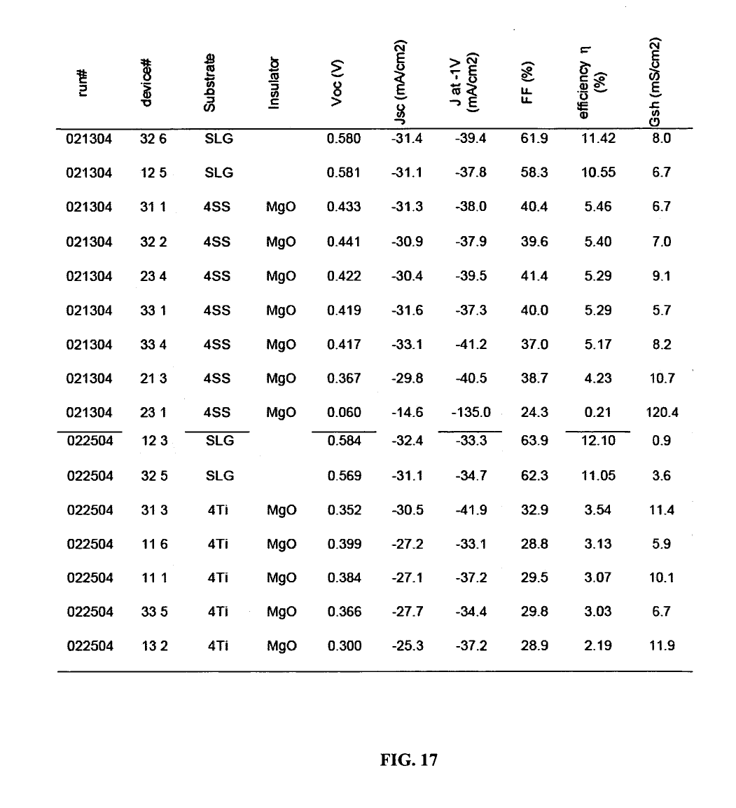

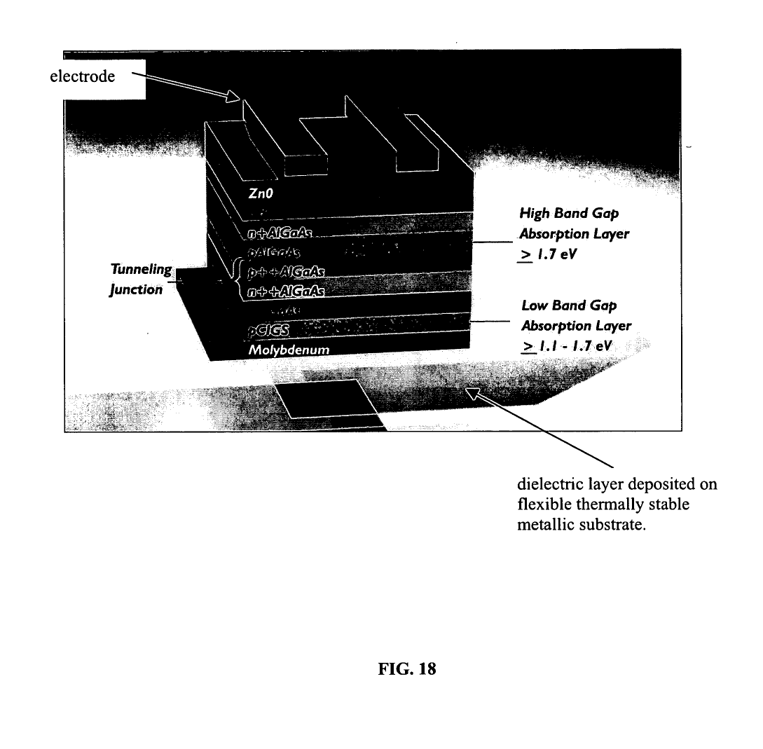

Representative data from prepared cells are summarized in the Table in FIG. 17. For example, the efficiency of a cell prepared on a 4SS/MgO substrate had Voc=0.433 V, Jsc=31.3 mA/cm² and a fill factor of 40.4% and 5.5% efficiency (021304-31-1).

The results show that a variety of flexible thermally stable substrates can be coated with a dielectric in a roll to roll process can be used to form functioning solar cells.

Although the present invention has been described in considerable detail with reference to certain preferred embodiments thereof, other versions are possible. For example, the dielectric insulated layer also allows solar cells similarly constructed, but with Gallium Arsenide (GaAs) as the photoactive layer and the insulated layer also allows for high temperature switch applications. Therefore the spirit and scope of the appended claims should not be limited to the description and the preferred versions contain within this specification.

1. An article comprising:
a flexible metallic substrate; and
a wide bandgap semiconductor film deposited on said conductive substrate, said insulating film being adherent to said substrate.

2. The article of claim 1 wherein the wide bandgap semiconductor has a bandgap of greater than 2 eV.

3. The article of claim 1 wherein the thermally stable substrate is chosen from the group consisting of stainless steel, titanium, molybdenum, aluminum, or alloys thereof.

4. The article of claim 1 wherein the wide bandgap semiconductor film is less than about 3 microns thick and is insulating with a potential difference of at least 187 volts between the metallic substrate and an electrode applied to the wide bandgap semiconductor film.

5. The article of claim 1 wherein the wide band gap semiconductor has a bandgap of greater than about 5 eV.

6. The article of claim 1 wherein said insulating film has dielectric constant of greater than about 7.

7. The article of claim 1 further comprising one or more electrodes on the insulating film.

8. A substrate for a photovoltaic cell comprising:
a flexible metallic substrate;
a coating of an wide band gap semiconductor deposited on the substrate by physical vapor deposition.

9. The substrate of claims 8 wherein said wide band gap semiconductor is deposited on the substrate by ion assisted physical vapor deposition.

10. The substrate of claim 8 further comprising a conductive film applied to a portion of said wide band gap semiconductor coating.

11. The method of claim 8 wherein said wide bandgap semiconductor has a bandgap of greater than 2 eV.

12. An article comprising:
a flexible thermally stable substrate;
a wide band gap semiconductor film deposited on an area of said flexible thermally stable substrate, said wide band gap semiconductor film adhering to said substrate;
a conductive film covering at least a portion of said area and electrically insulated from said substrate; and
a light absorbing semiconductor composition coating at least a portion of said conductive film area.

13. The article of claim 12 wherein said light absorbing semiconductor chosen from the group consisting of amorphous silicon, CdTe, or GaAs.

14. The article of claim 12 wherein the light absorbing semiconductor composition comprises copper.

15. The article of claim 3 wherein the light absorbing semiconductor composition is Cu(In₁₋ₓGaₓ)Se₂, CuInSe₂, CuInS₂, or CuGaSe₂.

16. The article of claim 12 wherein the wide band gap semiconductor material is a metal oxide or a metal nitride.

17. The article of claim 12 wherein the wide band gap semiconductor material is AlN or MgO.

18. The article of claim 12 wherein the conductive film forms isolated electrodes on the wide bandgap semiconductor film.

19. The article of claim 12 wherein the thermally stable substrate is stainless steel, titanium, molybdenum, aluminum, or alloys of these metals.

20. The article of claim 12 further comprising a layer of CdS.

21. The article of claim 12 wherein said cell has an efficiency of greater than 3%.

22. A method of making a thermally stable substrate for monolithic processing, the method comprising:
depositing a wide band gap semiconductor film on at least one area of a thermally stable substrate, said wide band gap semiconductor having a bandgap of at least 2 eV, by physical vapor deposition, ion assisted physical vapor deposition.

23. The method of claim 22 further comprising the act of depositing a conductive film on a at least a portion of said wide band gap semiconductor film.

24. The method of claim 22 further comprising the act of depositing a light absorbing semiconductor composition on said conductive film, said composition coating a portion of said conductive film.

25 The method of claim 22 wherein said substrate further include the act of being annealed above 450° C.

26. An article comprising:
a plurality of photovoltaic cells deposited on a wide bandgap semiconductor layer, said wide bandgap semiconductor layer deposited and adherent to a flexible substrate that is thermally stable above 450° C.

27. The article of claim 26 further comprising electrically interconnecting said photovoltaic cells in series.

28. The article of claim 26 wherein the wide bandgap semiconductor has a bandgap of at least 2 eV.

29. A method of making a photovoltaic cell comprising:
annealing a light absorbing semiconductor composition at a temperature sufficient to increase the grain size of the composition, said composition coating a portion of a conductive film, said conductive film covering a portion of a wide bandgap semiconductor, said wide bandgap semiconductor coating and adhering to portions of a thermally stable flexible substrate.

30. The method of claim 29 wherein the light absorbing semiconductor composition is Cu(In₁₋ₓGaₓ)Se₂, CuInSe₂, CuInS₂, or CuGaSe₂.

31. The method of claim 29 further comprising:
coating the thermally stable flexible substrate with a wide bandgap semiconductor to form a first layer on the thermally stable substrate;
coating said first layer selectively with a composition to form one or more electrically conductive areas on the first layer; and
coating said electrically conductive areas with a light absorbing semiconductor composition.

31. A tandem solar cell comprising:
a flexible substrate having an adherent wide bandgap semiconductor layer thereon;
areas of conducting material forming a first electrode deposited over a portion of said wide bandgap semiconductor layer, said conducting material forming an ohmic contact with a first solar cell material;
a first solar cell for converting short wavelength portion of the solar spectrum into electron hole pairs, said first cell deposited on said conducting material having a first layer including copper, indium, gallium and selenium and a second layer having gallium and arsenic on said area of insulating material;
a buffer layer having a tunneling junction, said buffer layer formed from n and p doped layers including aluminum, gallium, and arsenic on said first solar cell layer and having a bandgap greater that said first solar cell;
a second solar cell for converting long wavelength portion of the solar spectrum into electron hole pairs, said second cell having a first layer including aluminum, gallium, arsenic, and a second layer having cadmium and sulfur, said second solar cell layer having a band gap less than said first solar cell; and
a conductive transparent electrode covering said second solar cell and forming an ohmic contact with said second cell.

32. The tandem solar cell of claim 31 wherein the first solar cell absorbs solar radiation with energy from about 1.1 to 1.7 eV.

33. The tandem solar cell of claim 31 wherein the second solar cell absorbs solar radiation with energy greater than 1.7 eV.

34. The tandem solar cell of claim 31 wherein an antireflection layer is deposited on said conductive electrode.

35. The tandem solar cell of claim 31 wherein said wide bandgap semiconductor has a bandgap of greater that 2 eV.

36. The tandem solar cell of claim 31 wherein said first solar cell is CIGS.

37. The tandem solar cell of claim 31 wherein the electrode for said first solar cell includes molybdenum.

38. The tandem solar cell of claim 31 wherein said flexible substrate is chosen from the group consisting of stainless steel, titanium, molybdenum, aluminum, or alloys thereof.

39. A process for making a thin film tandem solar cell comprising:
forming a first solar cell on a conductive electrode formed on an wide bandgap semiconductor layer adhering to a flexible metal substrate, said first solar cell having a first layer including copper, indium, gallium and selenium and a second layer having gallium and arsenic on said area of insulating material;
depositing a buffer layer, said buffer layer including n and p doped layers and forming a tunneling junction; said layers including aluminum, gallium, and arsenic on said first solar cell layer, said buffer layer having a bandgap greater that said first solar cell;
forming a second solar cell for converting long wavelength portion of the solar spectrum into electron hole pairs, said second cell having a first layer and including aluminum, gallium, arsenic, and a second layer having cadmium and sulfur, said second solar cell layer having a band gap less than said first solar cell; and
depositing a conductive transparent electrode on said second solar cell and forming an ohmic contact with said second cell.

40. The process of claim 39 wherein further including the act of depositing areas of conducting material for a first electrode over a portion of an electrically wide bandgap semiconductor layer adhering to a metallic substrate, said conducting material forming an ohmic contact with a first solar cell material.

41. The process of claim 39 further including the act of annealing the first layer of said first solar cell above 500° C.

42. The process of claim 39 wherein said flexible metal substrate is chosen from the group consisting of stainless steel, titanium, molybdenum, aluminum, or alloys thereof.

43. A solar cell producing electric current, comprising:
a flexible conductive base;
an insulating layer formed on at least a portion of the flexible conductive base;
a conductive layer formed on at least a portion of the insulating layer; and
a light-absorption layer disposed above the conductive layer, wherein the light-absorption layer is a semiconductor; and
a transparent conductive top electrode.

44. The solar cell of claim 43 wherein the insulating layer is a wide bandgap semiconductor.

45. The solar cell of claim 43 wherein the light-absorption layer includes elements chosen from the group consisting of Cu, Ga, or Cd.

46. A method of manufacturing a solar cell with a flexible conductive base, comprising:
depositing a wide bandgap semiconductive layer on said flexible conductive base by physical vapor deposition, or ion assisted physical vapor deposition;
forming one or more electrically conductive electrodes on said wide bandgap semiconductive layer.

47. The method of claim 46 further including the act of forming a semiconductor light-absorption layer on said conductive electrodes.

48. The method of claim 46 wherein the light absorption layer is annealed above 450° C.
